(19) United States
(12) Patent Application Publication
(10) Pub. No.: US 2018/0251891 A1
(43) Pub. Date: Sep. 6, 2018

(54) VAPORIZER, FILM FORMING APPARATUS, AND TEMPERATURE CONTROL METHOD

(71) Applicant: TOKYO ELECTRON LIMITED, Tokyo (JP)

(72) Inventors: Takashi FUJIBAYASHI, Nirasaki-shi (JP); Naoki YOSHII, Tokyo (JP)

(21) Appl. No.: 15/971,173

(22) Filed: May 4, 2018

Related U.S. Application Data
(63) Continuation of application No. PCT/JP2016/076453, filed on Sep. 8, 2016.

(30) Foreign Application Priority Data
Nov. 10, 2015 (JP) 2015-220275

(51) Int. Cl. C23C 16/448; C23C 16/52

(52) U.S. Cl. CPC C23C 16/4481; C23C 16/52

(57) ABSTRACT

A vaporizer includes: a gas-liquid mixer for mixing a solution containing a precursor and a carrier gas; a nozzle for injecting the mixed solution; a vaporization chamber in which the injected solution is vaporized; a first temperature-adjustment-mechanism for adjusting a chamber temperature of the vaporization chamber; a second temperature-adjustment-mechanism for adjusting a mixing temperature of the gas-liquid mixer; a third temperature-adjustment-mechanism for adjusting a nozzle temperature of the nozzle; and a control device for controlling the first temperature-adjustment-mechanism to adjust the chamber temperature to a first temperature higher than a vaporization temperature of the precursor, for controlling the second temperature-adjustment-mechanism to adjust the mixing temperature to a second temperature lower than the first temperature, and for controlling the third temperature-adjustment-mechanism to adjust the nozzle temperature to a third temperature ranging from the first temperature to the second temperature and lower than a vaporization temperature of a solvent of the solution.

### CROSS-REFERENCE TO RELATED APPLICATIONS

This application is a bypass continuation application of international application No. PCT/JP2016/076453 having an international filing date of Sep. 8, 2016 and designating the United States, the international application being based upon and claiming the benefit of priority from Japanese Patent Application No. 2015-220275, filed on Nov. 10, 2015, the entire contents of which are incorporated herein by reference.

### TECHNICAL FIELD

Various aspects and embodiments of the present disclosure: relate to a vaporizer, a film forming apparatus, and a temperature control method.

### BACKGROUND

In the related art, a chemical vapor deposition (CVD) method is known as a method of forming a thin film. In such a CVD method, for example, a solution containing a precursor such as a metal complex (hereinafter referred to as a “precursor solution”) is vaporized by a vaporizer. A precursor gas thus obtained is used to perform a film formation process in a film formation chamber. In the vaporizer, for example, the precursor solution and a carrier gas are mixed in a gas-liquid mixer. The precursor solution mixed with the carrier gas is injected into a vaporization chamber through a nozzle. The vaporization chamber is heated to vaporize the injected precursor solution.

Incidentally, in the vaporizer, as the vaporization chamber is heated, the nozzle may increase in temperature together with the vaporization chamber. If the temperature of the nozzle increases excessively, the precursor solution is also heated when the precursor solution is injected into the vaporization chamber through the nozzle. Therefore, only a solvent in the precursor solution is vaporized earlier than the precursor so that the precursor is stuck inside the nozzle, which may result in clogging of the nozzle.

In order to address this problem, there has been proposed a technique for installing a member to be cooled in the nozzle and adjusting the temperature of the nozzle by cooling the member to be cooled.

However, when the temperature of the gas-liquid mixer is increased together with the vaporization chamber as the vaporization chamber is heated, the temperature adjustment of the nozzle is hindered by the influence of the transfer of heat from the gas-liquid mixer to the member to be cooled. For this reason, there is a failure to suppress the increase in temperature of the nozzle, whereby the precursor is stuck in the nozzle. Therefore, it is difficult to stably prevent the nozzle from clogging.

### SUMMARY

According to one embodiment of the present disclosure, a vaporizer includes: a gas-liquid mixer configured to mix a solution containing a precursor and a carrier gas; a nozzle configured to inject the solution containing the precursor mixed by the gas-liquid mixer; a vaporization chamber in which the solution containing the, precursor injected by the nozzle is vaporized; a first temperature adjustment mechanism configured to adjust a temperature of the vaporization chamber; a second temperature adjustment mechanism configured to adjust a temperature of the gas-liquid mixer; a third temperature adjustment mechanism configured to adjust a temperature of the nozzle; and a control device configured to control the first temperature adjustment mechanism to adjust the temperature of the vaporization chamber to a first temperature higher than a vaporization temperature of the precursor, to control the second temperature adjustment mechanism to adjust the temperature of the gas-liquid mixer to a second temperature lower than the first temperature, and to control the third temperature adjustment mechanism to adjust the temperature of the nozzle to a third temperature which falls within a temperature range between the first temperature and the second temperature and is lower than a vaporization temperature of a solvent of the solution.

According to another embodiment of the present disclosure, a film forming apparatus includes: a vaporizer configured to generate a precursor gas by vaporizing a solution containing a precursor; and a film formation chamber in which a film forming process is performed using the precursor gas generated by the vaporizer, wherein the vaporizer includes: a gas-liquid mixer configured to mix the solution containing the precursor and a carrier gas; a nozzle configured to inject the solution containing the precursor mixed by the gas-liquid mixer; a vaporization chamber in which the solution containing the precursor injected by the nozzle is vaporized; a first temperature adjustment mechanism configured to adjust a temperature of the vaporization chamber; a second temperature adjustment mechanism configured to adjust a temperature of the gas-liquid mixer; a third temperature adjustment mechanism configured to adjust a temperature of the nozzle and a control device configured to control the first temperature adjustment mechanism to adjust the temperature of the vaporization chamber to a first temperature higher than a vaporization temperature of the precursor, to control the second temperature adjustment mechanism to adjust the temperature of the gas-liquid mixer to a second temperature lower than the first temperature, and to control the third temperature adjustment mechanism to adjust the temperature of the nozzle to a third temperature which falls within a temperature range between the first temperature and the second temperature and is lower than a vaporization temperature of a solvent of the solution.

According to another embodiment of the present disclosure, a temperature control method performed by a vaporizer including: a gas-liquid mixer configured to mix a solution containing a precursor and a carrier gas; a nozzle configured to inject the solution containing the precursor mixed by the gas-liquid mixer; a vaporization chamber in which the solution containing the precursor injected by the nozzle is vaporized; a first temperature adjustment mechanism configured to adjust a temperature of the vaporization chamber; a second temperature adjustment mechanism configured to adjust a temperature of the gas-liquid mixer; and a third temperature adjustment mechanism configured to adjust a temperature of the nozzle, the method including: adjusting, by the first temperature adjustment mechanism, the temperature of the vaporization chamber to a first temperature higher than a vaporization temperature of the precursor; adjusting, by the second temperature adjustment mechanism, the temperature of the gas-liquid mixer to a second temperature lower than the first temperature; and adjusting, by the third temperature adjustment mechanism, the temperature of the nozzle to a third temperature which falls within a temperature range between the first temperature and the second temperature and is lower than a vaporization temperature of a solvent of the solution.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic view illustrating a configuration example of a film forming apparatus according to a first embodiment.

FIG. 2 is a schematic cross-sectional view illustrating a configuration example of a vaporizer according to the first embodiment.

FIG. 3 is a flowchart illustrating an example of a control method to control the flow of temperature according to the first embodiment.

FIG. 4 is a view showing examples of a solvent of a precursor solution.

FIG. 5A is a view showing the results of Examples 1 and 2 and Comparative Examples 1 and 2.

FIG. 5B is a view showing the results of Examples 3 and 4 and Comparative Examples 3 and 4.

FIG. SC is a view showing the results of Examples 5 and 6 and Comparative Examples 5 and 6.

FIG. 6 is a view showing the characteristic of Li(TMHD) and the characteristic of Co(TMHD)₃.

FIG. 7 is a schematic view illustrating a configuration example of a film forming apparatus according to another first embodiment.

FIG. 8 is a schematic view illustrating a configuration example of a film forming apparatus according to another second embodiment.

### DETAILED DESCRIPTION

Embodiments of a vaporizer, a film forming apparatus and a temperature control method according to the present disclosure will now be described in detail with reference to the drawings. Throughout the drawings, the same or equivalent elements, parts and portions are denoted by the same reference numerals.

### First Embodiment

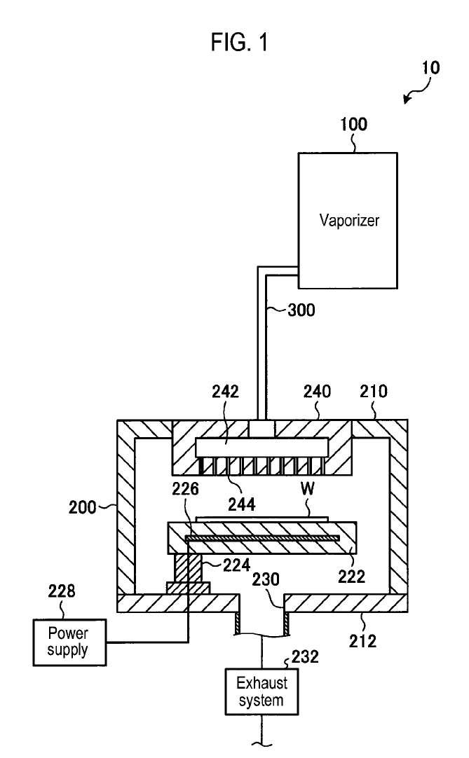

First, a film fi rating apparatus according to a first embodiment will be described with reference to the drawings. FIG. 1 is a schematic view illustrating a configuration example of the film forming apparatus according to the first embodiment. The film forming apparatus 10 illustrated in FIG. 1 forms a metal oxide film on a substrate to be processed, for example, a semiconductor wafer (hereinafter simply referred to as a “wafer”) W, using a CVD method. The film forming apparatus 10 includes a vaporizer 100 and a film formation chamber 200. The vaporizer 100 and the film formation chamber 200 are interconnected by a pipe 300.

The vaporizer 100 vaporizes a solution containing a precursor (hereinafter referred to as a “precursor solution” as appropriate) to generate a precursor gas. The precursor is, for example, Li(TMHD). The precursor gas generated by the vaporizer 100 is supplied into the film formation chamber 200 via the pipe 300. Details of the vaporizer 100 will be described later.

The film formation chamber 200 uses the precursor gas generated by the vaporizer 100 to perform a film formation process on the wafer W. The film formation chamber 200 has, for example, a substantially cylindrical side wall and includes a susceptor 222 on which the wafer W is mounted horizontally, in an internal space surrounded by the side wall, a ceiling wall 210 and a bottom wall 212. The side wall, the ceiling wall 210 and the bottom wall 212 are made of, for example, metal such as aluminum, stainless steel or the like. The susceptor 222 is supported by a plurality of cylindrical support members 224 (only one shown in this figure). Further, a heater 226 is embedded in the susceptor 222. A temperature of the wafer W mounted on the susceptor 222 can be adjusted by controlling electric power applied from a power supply 228 to the heater 226.

An exhaust port 230 is formed in the bottom wall 212 of the film formation chamber 200, An exhaust system 232 is connected to the exhaust port 230. The interior of the film formation chamber 200 can be depressurized to a predetermined degree of vacuum by the exhaust system 232.

A shower head 240 is installed in the ceiling wall 210 of the film formation chamber 200. The pipe 300 is connected to the shower head 240. The precursor gas generated in the vaporizer 100 is introduced into the shower head 240 via the pipe 300. The shower head 240 has a diffusion chamber 242 and a plurality of gas discharge holes 244 communicating with the diffusion chamber 242. The precursor gas introduced into the diffusion chamber 242 of the shower head 240 via the pipe 300 is discharged from the gas discharge holes 244 toward the wafer W mounted on the susceptor 222.

In the film forming apparatus 10 configured as above, the precursor gas from the vaporizer 100 is supplied in the following manner. When a precursor solution is supplied from a precursor solution supply source (not shown) into the vaporizer 100 and a carrier gas is supplied from a carrier gas supply source (not shown) into the vaporizer 100, the precursor solution is discharged, together with the carrier gas, in the form of droplets into a vaporization chamber installed inside the vaporizer 100. The precursor gas is generated by vaporizing the precursor solution. The precursor gas generated in the vaporizer 100 is supplied into the film formation chamber 200 via the pipe 300 so that a desired film forming process is performed on the wafer W in the film formation chamber 200.

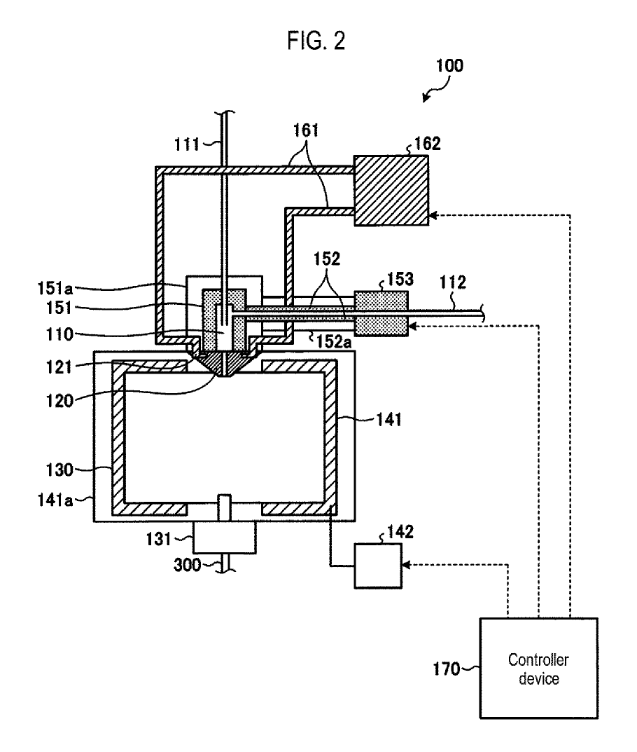

Next, a configuration example of the vaporizer 100 will be described. FIG. 2 is a schematic cross-sectional view illustrating a configuration example of the vaporizer according to the first embodiment. The vaporizer 100 includes a gas-liquid mixer 110, a nozzle 120, a vaporization chamber 130, a heater 141, a heater power supply 142, a heat medium passage 151, a heat medium passage 152, a heat medium unit 153, a heat medium transport pipe 161, a heat medium unit 162 and a control device 170.

The gas-liquid mixer 110 mixes the precursor solution and the carrier gas. A precursor solution supply pipe 111 and a carrier gas supply pipe 112 are connected to the gas-liquid mixer 110. The precursor solution is supplied from the precursor solution supply source (not shown) into the gas-liquid mixer 110 via the precursor solution supply pipe 111. The carrier gas is supplied from the carrier gas supply source (not shown) into the gas-liquid mixer 110 via the carrier gas supply pipe 112. The precursor solution mixed with the carrier gas by the gas-liquid mixer 110 flows into the nozzle 120.

The nozzle 120 injects the precursor solution mixed with the carrier gas by the gas-liquid mixer 110 into the vaporization chamber 130. A heat medium passage 121 is formed inside the nozzle 120. The heat medium passage 121 is formed in, for example, an annular shape, inside the nozzle 120. A heat medium adjusted to have a predetermined temperature by the heat medium unit 162 is supplied into the heat medium passage 121 via the heat medium transport pipe 161.

The vaporization chamber 130 vaporizes the precursor solution injected by the nozzle 120. Specifically, the vaporization chamber 130 vaporizes the precursor solution using heat transferred from the heater 141. The pipe 300 is connected to the vaporization chamber 130 via an exhauster 131. The precursor gas obtained by vaporizing the precursor solution in the vaporization chamber 130 is discharged into the pipe 300 by the exhauster 131 and is supplied into the film formation chamber 200 via the pipe 300.

The heater 141 is installed outside the vaporization chamber 130 so as to cover the periphery of the vaporization chamber 130. The heater 141 receives a current supplied from the heater power supply 142, thereby generating heat. In addition, the periphery of the heater 141 is covered with a heat insulating material 141a.

The heater power supply 142 adjusts a temperature of the vaporization chamber 130 under the control of the control device 170. More specifically, upon receiving a “first temperature control signal” from the control device 170, the heater power supply 142 flows a predetermined current through the heater 141 to cause the heater 141 to generate heat. Thus, the temperature of the vaporization chamber 130 is adjusted to a temperature T1 higher than the vaporization temperature of the precursor. If the temperature of the vaporization chamber 130 rises excessively, the precursor is thermally decomposed and converted into another substance when the precursor solution is vaporized. Therefore, it is preferable that the temperature T1 is higher than the vaporization temperature of the precursor and is lower than a temperature at which the precursor is thermally decomposed. The heater power supply 142 is an example of a “first temperature adjustment mechanism” and the temperature T1 is an example of the “first temperature”.

The heat medium passage 151 is formed outside the gas-liquid mixer 110 so as to cover the periphery of the gas-liquid mixer 110. The heat medium passage 151 is connected to the heat medium passage 152 and circulates a heat medium supplied from the heat medium unit 153 via the heat medium passage 152. In addition, the periphery of the heat medium passage 151 is covered with a heat insulating material 151a.

The heat medium passage 152 is formed outside the carrier gas supply pipe 112 connected to the gas-liquid mixer 110 so as to cover the periphery of the carrier gas supply pipe 112. The heat medium passage 152 is connected to the heat medium unit 153 and circulates a heat medium supplied from the heat medium unit 153. In addition, the periphery of the heat medium passage 152 is covered with a heat insulating material 152a.

The heat medium unit 153 adjusts the temperature of the gas-liquid mixer 110 and the temperature of the carrier gas supply pipe 112 under the control of the control device 170. Specifically, upon receiving a “second temperature control signal” from the control device 170, the heat medium unit 153 adjusts the temperature of the gas-liquid mixer 110 and the temperature of the carrier gas supply pipe 112 to a temperature T2 lower than the temperature T1 by circulating the heat medium using the heat medium passage 151 and the heat medium passage 152. That is to say, the heat medium adjusted to have a predetermined temperature by the heat medium unit 153 flows into the heat medium passage 152, circulates through the heat medium passage 152 while heating or cooling the carrier gas supply pipe 112, and subsequently flows into the heat medium passage 151. The heat medium flowing into the heat medium passage 151 circulates through the heat medium passage 151 while heating or cooling the gas-liquid mixer 110, returns to the heat medium unit 153 via the heat medium passage 152, and again circulates through the heat medium passage 152 and the heat medium passage 151 after being adjusted to have the predetermined temperature by the heat medium unit 153. As a result, the temperature of the gas-liquid mixer 110 and the temperature of the carrier gas supply pipe 112 are adjusted to the temperature T2 lower than the temperature T1. The heat medium unit 153 is an example of a “second temperature adjustment mechanism” and the temperature T2 is an example of the “second temperature”.

The heat medium transport pipe 161 is connected to the heat medium passage 121 formed inside the nozzle 120, and transports the heat medium adjusted to have the predetermined temperature by the heat medium unit 162 to the heat medium passage 121.

The heat medium unit 162 adjusts the temperature of the nozzle 120 under the control of the control device 170. Specifically, upon receiving a “third temperature control signal” from the control device 170, the heat medium unit 162 adjusts the temperature of the nozzle 120 to a temperature T3 by circulating the heat medium using the heat medium transport pipe 161 and the heat medium passage 121 formed inside the nozzle 120. The temperature T3 falls within a temperature range between the temperature T1 and the temperature T2 and is lower than the vaporization temperature of the solvent of the precursor solution. That is to say, the heat medium adjusted to have: the predetermined temperature by the heat medium unit 162 flows into the heat medium passage 121 in the nozzle 120 via the heat medium sport pipe 161, circulates through the heat medium passage 121 while heating or cooling the nozzle 120, returns to the heat medium unit 162 via the heat medium transport pipe 161, and again circulates through the heat medium transport pipe 161 and the heat medium passage 121 after being adjusted to have the predetermined temperature by the heat medium unit 162. As a result, the temperature of the nozzle 120 is adjusted to the temperature T3. The heat medium unit 162 is an example of a “third temperature adjustment mechanism” and the temperature T3 is an example of the “third temperature”.

The control device 170 includes, for example, a central processing unit (CPU), a storage device such as a memory and controls various operations of the vaporizer 100 by reading out and executing a program stored in the storage device. For example, the control device 170 controls various parts of the vaporizer 100 so as to perform a temperature control method to be described later. As an example, the control device 170 adjusts the temperature of the vaporization chamber 130 to the temperature T1 higher than the vaporization temperature of the precursor by the heater power supply 142. Then, the control device 170 adjusts the temperature of the gas-liquid mixer 110 to the temperature T2 lower than the temperature T1 by the heat medium unit 153. Subsequently, the control device 170 adjusts the temperature of the nozzle 120 to the temperature T3, which falls within the temperature range between the temperature T1 and the temperature T2 and is lower than the vaporization temperature of the solvent of the precursor solution, by the heat medium unit 162. Here, the temperature adjustment by the heater power supply 142, the temperature adjustment by the heat medium unit 153 and the temperature adjustment by the heat medium unit 162 are respectively performed based on, for example, “the first temperature adjustment signal”, “the second temperature adjustment signal” and “the third temperature adjustment signal” as described above. The temperature T3 corresponds to an intermediate value between the temperature T1 and the temperature T2 and is lower than the vaporization temperature of the solvent of the precursor solution. The precursor is, for example, Li(TMHD).

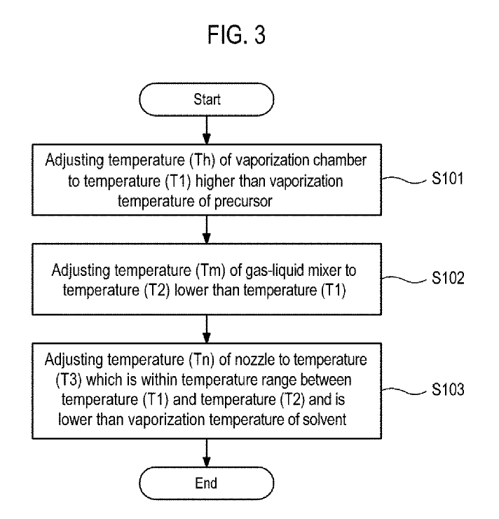

Next, a temperature control method performed by the vaporizer 100 according to the present embodiment will be described. FIG. 3 is a flowchart illustrating an example of a flow of the temperature control method according to the first embodiment. In the example of FIG. 3, it is assumed that the precursor is Li(TMHD).

As illustrated in FIG. 3, the control device 170 of the vaporizer 100 adjusts the temperature Th of the vaporization chamber 130 to the temperature T1 higher than the vaporization temperature of the precursor by the heater power supply 142 (Step S101). Here, assuming that the vaporization temperature of the precursor is Tsol [degrees C.], the temperature condition to be satisfied by the vaporization chamber 130 is expressed by the following equation (1).

Th>Tsol (1)

In addition, as described above, it is preferable that the temperature T1, namely the temperature Th of the vaporization chamber 130, is lower than the temperature at which the precursor is thermally decomposed. That is to say, since the thermal decomposition temperature of Li(TMHD) used as the precursor is 280 degrees C., the following equation (2) is derived from the above equation (1).

Tsol<Th<280 (2)

Subsequently, the control device 170 adjusts a temperature Tm of the gas-liquid mixer 110 to the temperature T2 lower than the temperature T1 by the heat medium unit 153 (Step S102). At this time, the control device 170 adjusts the temperature of the carrier gas supply pipe 112 to the temperature T2, together with the temperature of the gas-liquid mixer 110.

Subsequently, the control device 170 adjusts a temperature Tn of the nozzle 120 to the temperature T3, which falls within the temperature range between the temperature T1 and the temperature T2 and is lower than the vaporization temperature of the solvent of the precursor solution, by the heat medium unit 162 (Step S103). In the present embodiment, the control device 170 adjusts the temperature Tn of the nozzle 120 to the temperature T3 which corresponds to an intermediate value between the temperature T1 and the temperature T2 and is lower than the vaporization temperature of the solvent of the precursor solution.

Here, assuming that the vaporization temperature of the solvent of the precursor solution is Tsov [degrees C.], the temperature condition to be satisfied by the nozzle 120 is expressed the following equation (3).

Tn=(Th+Tm)/2<Tsov (3)

The solvent of the precursor solution is selected so that the temperature condition expressed by the above equation (2) and the temperature condition expressed by the above equation (3) are satisfied. In other words, the solvent of the precursor solution is selected so that the following equations (4) and (5) are satisfied.

Ph<29 (4)

Tsov>{11.94In(Ph)+157.38+Tm}/2 (5)

Where, Ph represents an internal pressure [kPa] of the vaporization chamber.

Here, a process of deriving the above equation (4) will be described. The following equation (6) is derived from an approximation equation of a vapor pressure curve of Li(TMHD) used as the precursor.

Tsol=11.94In(Ph)+157.38 (6)

Substituting the above equation (6) into the above equation (2) and eliminating Tsol yields the above equation (4).

Next, a process of deriving the above equation (5) will be described. When the temperature condition expressed by the above equation (1) and the temperature condition expressed by the above equation (3) are simultaneously satisfied, the following equation (7) is derived.

Tsol<Th<2Tsov−Tm (7)

Substituting the above equation (6) into the above equation (7) and eliminating Tsol yields the above equation (5).

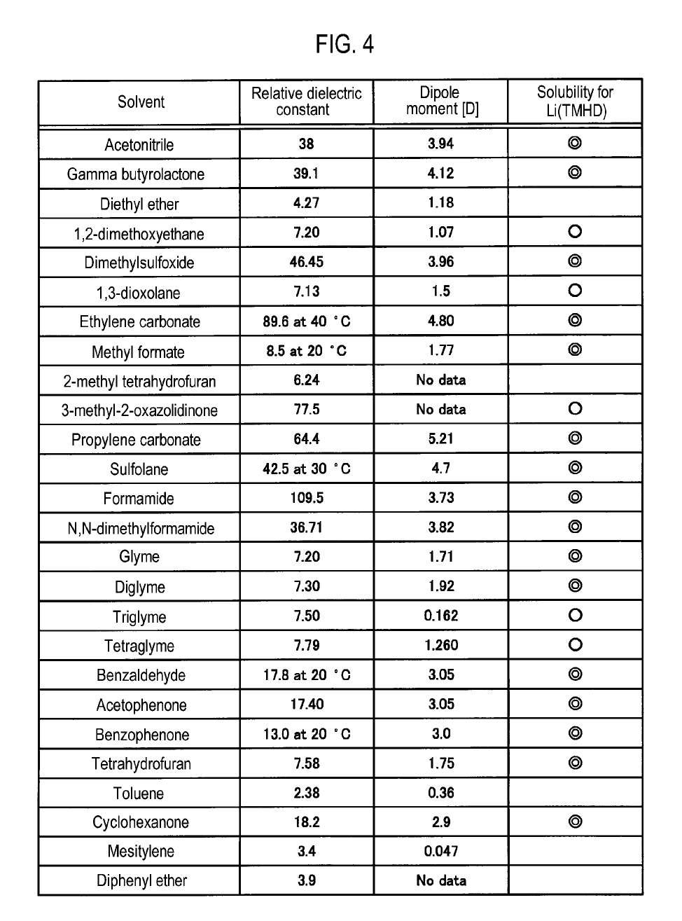

Examples of the solvent of precursor solution satisfying the above equations (4) and (5) may include solvents shown in FIG. 4. FIG. 4 is a view showing examples of the solvent of the precursor solution. That is to say, examples of the solvent of the precursor solution may include acetonitrile, gamma butyrolactone, diethyl ether, 1,2-dimethoxyethane, dimethylsulfoxide, 1,3-dioxolane, ethylene carbonate, methyl formate, 2-methyl tetrahydrofuran, 3-methyl-2-oxazolidinone, propylene carbonate, sulfolane, formamide, N,N-dimethylformamide, glyme, diglyme, triglyme, tetraglyme, benzaldehyde, acetophenone, benzophenone, tetrahydrofuran, toluene, cyclohexanone, mesitylene, and diphenyl ether. In particular, from the viewpoint of solubility for Li(TMHD) used as the precursor, solvents having a relative dielectric constant of 7.0 or more and a dipole moment of 1.7D or more, for example, acetonitrile, gamma butyrolactone, dimethylsulfoxide, ethylene carbonate, methyl formate, propylene carbonate, sulfolane, formamide, N,N-dimethylformamide, glyme, diglyme, benzaldehyde, acetophenone, benzophenone, tetrahydrofuran, and cyclohexanone may be used.

The process procedure shown in FIG. 3 is not limited to the sequence described above but may be appropriately changed unless a conflict arises. For example, Steps S101 and S102 may be executed in parallel.

As described above, according to the vaporizer 100 of the first embodiment, the temperature of the vaporization chamber 130 is adjusted to the temperature T1 higher than the vaporization temperature of the precursor, the temperature of the gas-liquid mixer 110 is adjusted to the temperature T2 lower than the temperature T1, and the temperature of the nozzle 120 is adjusted to the temperature T3 which falls within the temperature range between the temperature T1 and the temperature T2 and is lower than the vaporization temperature of the solvent of the precursor solution. In this way, since the temperature of the nozzle 120 is adjusted independently of the temperature of the vaporization chamber 130 and the temperature of the gas-liquid mixer 110, the nozzle 120 can be appropriately cooled down, thus preventing the precursor from sticking inside the nozzle 120. As a result, according to the vaporizer 100 of the first embodiment, it is possible to stably prevent the nozzle 120 from clogging.

Hereinafter, the disclosed temperature control method will be described by way of Examples. It should be noted, however, that the disclosed temperature control method is not limited to the following Examples.

### Examples 1 to 6

in Examples 1 to 6, the temperature Th of the vaporization chamber 130 was adjusted to the temperature T1 higher than the vaporization temperature Tsol of Li(TMHD) used as the precursor, the temperature Tm of the gas-liquid mixer 110 was adjusted to the temperature T2 lower than the temperature T1, and the temperature Tn of the nozzle 120 was adjusted to the temperature T3 which corresponds to an intermediate value between the temperature T1 and the temperature T2 and is lower than the vaporization temperature Tsov of the solvent Y of the precursor solution.

Further, in Examples 1 to 6, the following solvents were used as the solvent Y of the precursor solution.

Examples 1 and 2: mesitylene

Examples 3, 4: Toluene

Examples 5 and 6: tetrahydrofuran

### Comparative Examples 1 and 2

In Comparative Examples 1 and 2, unlike Examples 1 and 2, the temperature Th of the vaporization chamber 130 was adjusted to a temperature lower than the vaporization temperature Tsol of Li(TMHD) used as the precursor. Comparative Examples 1 and 2 are the same as Examples 1 and 2 in other respects.

### Comparative Examples 3 and 4

In Comparative Examples 3 and 4, unlike Examples 3 and 4, the temperature Th of the vaporization chamber 130 was adjusted to a temperature lower than the vaporization temperature Tsol of Li(TMHD) used as the precursor. Comparative Examples 3 and 4 are the same as Examples 3 and 4 in other respects.

### Comparative Example 5

In Comparative Example 5, unlike Examples 5 and 6, the temperature Th of the vaporization chamber 130 was adjusted to a temperature lower than the vaporization temperature Tsol of Li(TMHD) used as the precursor, and the temperature Tn of the nozzle 120 was adjusted to a temperature which corresponds to an intermediate value between the temperature T1 and the temperature T2 and is higher than the vaporization temperature Tsov of the solvent Y of the precursor solution. Comparative Example 5 is the same as Examples 5 and 6 in other respects.

### Comparative Example 6

In Comparative Example 6, unlike Examples 5 and 6, the temperature Th of the vaporization chamber 130 was adjusted to a temperature lower than the vaporization temperature Tsol of Li(TMHD) used as the precursor. Comparative Example 6 is the same as Examples 5 and 6 in other respects.

### Results of Examples 1 to 6 and Comparative Examples 1 to 6

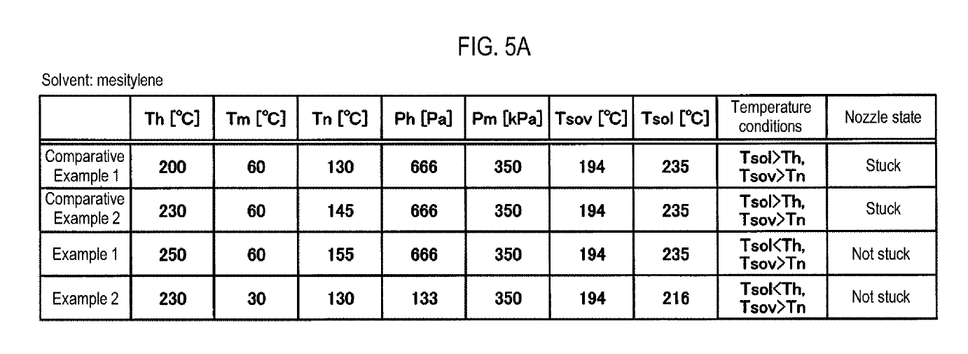

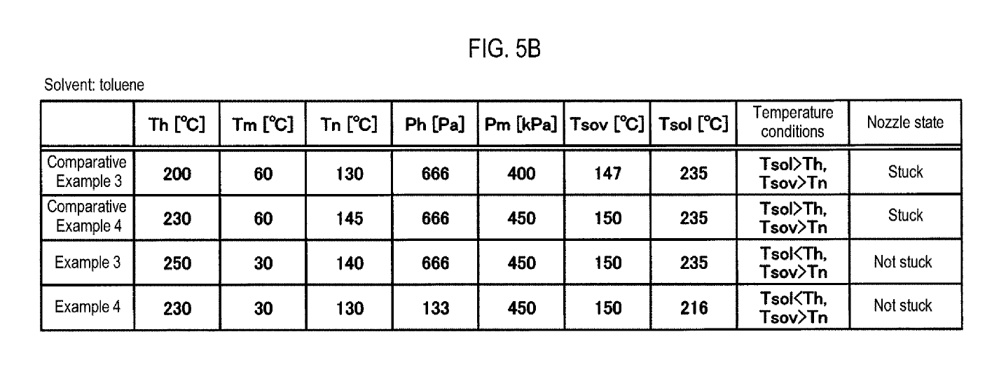

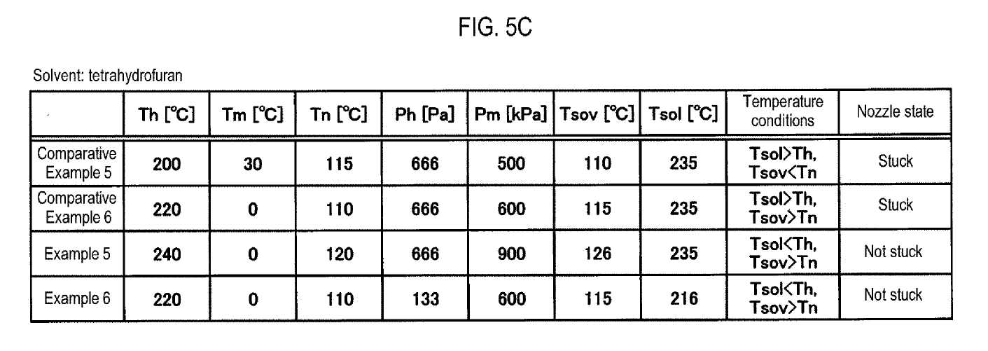

FIG. 5A is a view showing the results of Examples 1 and 2 and Comparative Examples 1 and 2. FIG. 5B is a view showing the results of Examples 3 and 4 and Comparative Examples 3 and 4. FIG. 5C is a view showing the results of Examples 5 and 6 and Comparative Examples 5 and 6.

As shown in FIGS. 5A to 5C, whichever of mesitylene, toluene and tetrahydrofuran is used as the solvent Y, the temperature Th of the vaporization chamber 130 is adjusted to the temperature T1, the temperature Tm of the gas-liquid mixer 110 is adjusted to the temperature T2, and the temperature Tn of the nozzle 120 is adjusted to the temperature T3, thereby avoiding the precursor from sticking inside the nozzle 120.

### Second Embodiment

A second embodiment is different from the first embodiment in that Li(TMHD) and Co(TMHD)₃ are used as the precursor. Therefore, description of the same configuration as that in the first embodiment will not be repeated.

In the film forming apparatus 10 of the second embodiment, the vaporizer 100 vaporizes a precursor solution to generate a precursor gas. In the present embodiment, the precursor is Li(TMHD) and Co(TMHD)₃ and the precursor solution is a mixed solution containing Li(TMHD) and Co(TMHD)₃ as the precursor. The precursor gas generated by the vaporizer 100 is supplied into the film formation chamber 200 via the pipe 300.

In the case where the precursor solution is the mixed solution containing Li(TMHD) and Co(TMHD)₃, the solvent of the precursor solution is selected so that the following equations (8) and (9) are satisfied.

Ph<29 (8)

Tsov>{11.94In(Ph)+157.38+Tm}/2 (9)

Where, Ph represents an internal pressure [kPa] of the vaporization chamber.

Hereinafter, a process of deriving the above equations (8) and (9) will be described.

Assuming that the precursor is only Li(TMHD), the vaporization temperature of the precursor is Tsol, Li [degrees C.] and the temperature of the vaporization chamber 130 is Th, Li, the temperature condition to be satisfied by the vaporization chamber 130 is expressed by the following equation (10).

Th, Li>Tsol, Li (10)

The temperature Th, Li of the vaporization chamber 130 may he lower than a temperature at which the precursor is thermally decomposed. That is to say, since the thermal decomposition temperature of Li(TMHD) is 280 degrees C., the following equation (11) is derived from the above equation (10).

Tsol, Li<Th, Li<280 (11)

Assuming that the precursor is only Li(TMHD), the vaporization temperature of the solvent of the precursor solution is Tsov, Li, the temperature of the nozzle 120 is Tn, Li, and the temperature of the gas-liquid mixer 110 is Tm, Li, the temperature condition to be satisfied by the nozzle 120 is expressed by the following equation (12).

Tn, Li=(Th, Li+Tm, Li)/2<Tsov, Li (12)

The following equation (13) is derived from an approximation equation of a vapor pressure curve of Li(TMHD).

Tsol, Li=11.94In(Ph, Li)+157.38 (13)

Where, Ph, Li represents an internal pressure [kPa] of the vaporization chamber when assuming that the precursor is only Li(TMHD).

Substituting the above equation (13) into the above equation (11) and eliminating Tsol, Li, yields the below equation (14).

Ph, Li<29 (14)

Further, the following equation (15) is derived from the above equations (10) and (12).

Tsol, Li<Th, Li<2Tsov, Li−Tm, Li (15)

Substituting the above equation (13) into the above equation (15) and eliminating Tsol, Li, yields the following equation (16).

Tsov, Li>{11.94In(Ph, Li)+157.38+Tm, Li}/2 (16)

On the other hand, assuming that the precursor is only Co(TMHD)₃, the vaporization temperature of the precursor is Tsol, Co [degrees C.], and the temperature of the vaporization chamber 130 is Th, Co, the temperature condition to be satisfied by the vaporization chamber 130 is expressed by the following equation (17).

Tb, Co>Tsol, Co (17)

The temperature Th, Co of the vaporization chamber 130 may be lower than a temperature at which the precursor is thermally decomposed. That is to say, since the thermal decomposition temperature of Co(TMHD)₃ is 250 degrees C., the following equation (18) is derived from the above equation (17).

Tsol, Co<Th, Co<250 (18)

Assuming that the precursor is only Co(TMHD)₃, the vaporization temperature of the solvent of the precursor solution is Tsov, Co, the temperature of the nozzle 120 is Tn, Co, and the temperature of the gas-liquid mixer 110 is Tm, Co, the temperature condition to he satisfied by the nozzle 120 is expressed by the following equation (19).

Tn, Co=(Th, Co+Tm, Co)/2<Tsov, Co (19)

The following equation (20) is derived from an approximation equation of a vapor pressure curve of Co(TMHD)₃.

Tsol, Co=1.7.744In(Ph, Co)+45.483 (20)

Where, Ph, Co represents an internal pressure [kPa] of the vaporization chamber when assuming that the precursor is only Co(TMHD)₃.

Substituting the above equation (20) into the above equation (18) and eliminating Tsol, Co, yields the following equation (21).

Ph, Co<101 (21)

The following equation (22) is derived from the above equations (17) and (19).

Tsol, Co<Th, Co<2Tsov, Co—Tm, Co (22)

Substituting the above equation (20) into the above equation (22) and eliminating Tsol, Co, yields the following equation (23).

Tsov, Co>{17.744In(Ph, Co)+45.483+Tm, Co}/2 (23)

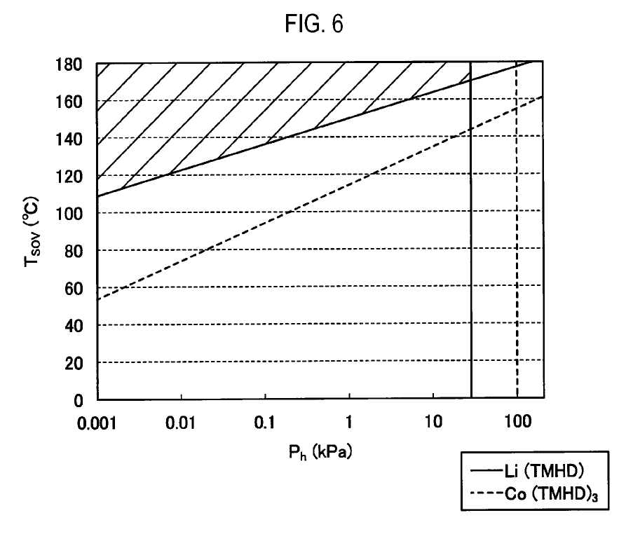

Therefore, when the precursor solution is the mixed solution containing Li(TMHD) and Co(TMHD)₃, the above-mentioned equations (14) and (16) are satisfied as the characteristic of Li(TMHD) and the above-mentioned (21) and (23) are satisfied as the characteristic of Co(TMHD)₃. The characteristic of Li(TMHD) and the characteristic of Co(TMHD)₃ are expressed by a graph shown in FIG. 6. FIG. 6 is a view explaining a graph showing the characteristic of Li(TMHD) and the characteristic of Co(TMHD)₃. In FIG. 6, a solid line indicates the characteristic of Li(TMHD) and a broken line indicates the characteristic of Co(TMHD)₃. As can be seen from a shaded portion in FIG. 6, when the above-mentioned equations (14) and (16) are satisfied as the characteristic of Li(TMHD), the above-mentioned equations (21) and (23) are also satisfied as the characteristic of Co(TMHD)₃. That is to say, the above-mentioned equations (8) and (9) are derived from the above-mentioned equations (14) and (16). Therefore, when the precursor solution is the mixed solution containing Li(TMHD) and Co(TMHD)₃, the solvent of the precursor solution is selected so that the above-mentioned equations (8) and (9) are satisfied.

As described above, according to the vaporizer of the second embodiment, when Li(TMHD) and Co(TMHD)₃ are used as the precursor, the solvent of the precursor solution is selected so that the above-mentioned equations (8) and (9) are satisfied. As a result, according to the vaporizer 100 of the second embodiment, it is possible to stably suppress the nozzle 120 from clogging, as in the first embodiment.

### Other Embodiments

While in the above embodiments, the example in which the film forming apparatus 10 includes the single vaporizer 100 for the single film formation chamber 200 has been described, the present disclosure is not limited thereto. For example, the film forming apparatus 10 may include two vaporizers for the single film formation chamber 200. Hereinafter, as a film forming apparatus according to other embodiments, a film forming apparatus including two vaporizers for the single film formation chamber 200 will be described.

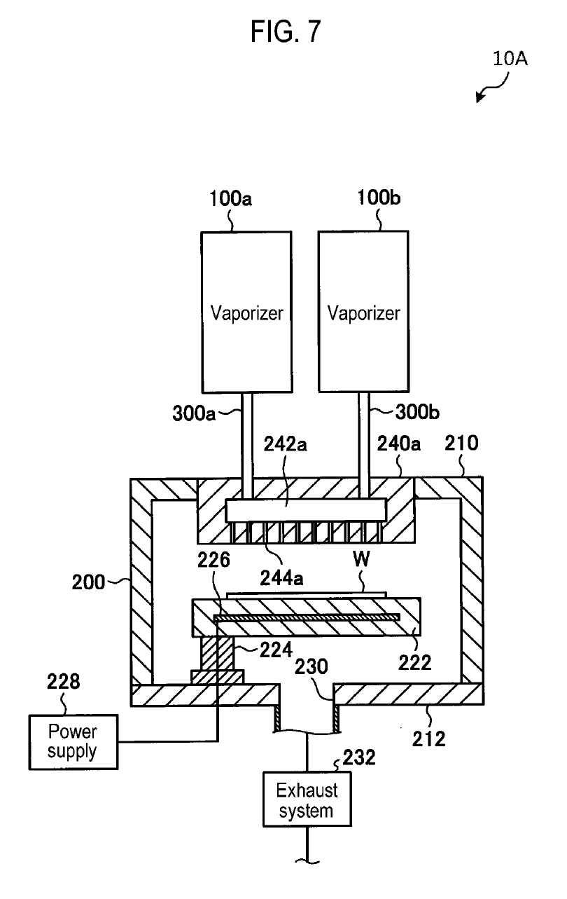

FIG. 7 is a schematic view illustrating a configuration example of a film forming apparatus according to an alternate first embodiment. A film forming apparatus 10A according to the alternate first embodiment is different from the film forming apparatus 10 illustrated in FIG. 1 in that the former includes two vaporizers for the single film formation chamber 200. Therefore, description of the same configurations as that of the film forming apparatus 10 illustrated in FIG. 1 will not be repeated.

The film forming apparatus 10A illustrated in FIG. 7 includes vaporizers 100a and 100b and the film formation chamber 200. The vaporizer 100a and the film formation chamber 200 are interconnected by a pipe 300a, and the vaporizer 100b and the film formation chamber 200 are interconnected by a pipe 300b.

The vaporizer 100a vaporizes a precursor solution containing Li(TMHD) as a precursor to generate a precursor gas. The precursor gas generated by the vaporizer 100a is supplied into the film formation chamber 200 via the pipe 300a. The vaporizer 100a has the same configuration as that of the vaporizer 100 illustrated in FIG. 1.

In the vaporizer 100a, the solvent of the precursor solution is selected so that the temperature condition related to Li(TMHD) used as the precursor is satisfied, namely so that the following equations (24) and (25) are satisfied.

Ph<29 (24)

Tsov>{11.94In(Ph)+157.38+Tm}/2 (25)

Where, Ph represents an internal pressure [kPa] of the vaporization chamber 130, Tsov represents the vaporization temperature [degrees C.] of the solvent of the precursor solution, and Tm represents the temperature [degrees C.] of the gas-liquid mixer 110.

The vaporizer 100b vaporizes a precursor solution containing Co(TMHD)₃ as a precursor to generate a precursor gas. The precursor gas generated by the vaporizer 100b is supplied into the film formation chamber 200 via the pipe 300b. The vaporizer 100b has the same configuration as that of the vaporizer 100 illustrated in FIG. 1.

In the vaporizer 100b, the solvent of the precursor solution is selected so that the temperature condition related to Co(TMHD)₃ used as the precursor is satisfied, namely so that the following equations (26) and (27) are satisfied.

Ph<101 (26)

Tsov>{17.744In(Ph)+45.483+Tm}/2 (27)

In the film forming apparatus 10A illustrated in FIG. 7, a shower head 240a is installed in the ceiling wall 210 of the film formation chamber 200. The pipe 300a and the pipe 300b are connected to the shower head 240a. The precursor gas generated in the vaporizer 100a (i.e., a precursor gas obtained by vaporizing the precursor solution containing Li(TMHD) used as the precursor) is introduced into the shower head 240a via the pipe 300a. In addition, the precursor gas generated in the vaporizer 100b (i.e., a precursor gas obtained by vaporizing the precursor solution containing Co(TMHD)₃ used as the precursor) is introduced into the shower head 240a via the pipe 300b. The shower head 240a includes a diffusion chamber 242a and a plurality of gas discharge holes 244a communicating with the diffusion chamber 242a. The precursor gas introduced into the diffusion chamber 242a of the shower head 240a via the pipe 300a and the precursor gas introduced into the diffusion chamber 242a of the shower head 240a via the pipe 300b are mixed in the diffusion chamber 242a and are discharged from the gas discharge holes 244a toward the wafer W mounted on the susceptor 222.

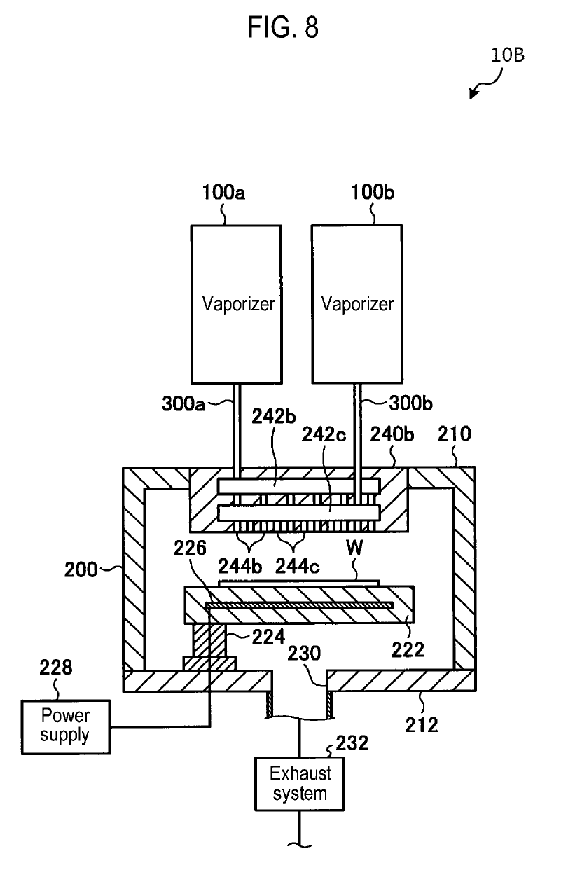

FIG. 8 is a schematic view illustrating a configuration example of a film forming apparatus according to an alternate second embodiment. A film forming apparatus 10B according to the alternate second embodiment is different from the film forming apparatus 10A illustrated in FIG. 7 in terms of the structure of the shower head. Therefore, description of the same configurations as that of the film forming apparatus 10A illustrated in FIG. 7 will not be repeated.

In the film forming apparatus 10B illustrated in FIG. 8, a shower head 240b is installed in the ceiling wall 210 of the film formation chamber 200. The pipe 300a and the pipe 300b are connected to the shower head 240b. The precursor gas generated in the vaporizer 100a (i.e., a precursor gas obtained by vaporizing the precursor solution containing Li(TMHD) used as the precursor) is introduced into the shower head 240h via the pipe 300a. In addition, the precursor gas generated in the vaporizer 100b (i.e., a precursor gas obtained by vaporizing the precursor solution containing Co(TMHD)₃ used as the precursor) is introduced into the shower head 240b via the pipe 300b. The shower head 240b includes a diffusion chamber 242b, a plurality of gas discharge holes 244b communicating with the diffusion chamber 242b, a diffusion chamber 242c and a plurality of gas discharge holes 244c communicating with the diffusion chamber 242c. The precursor gas introduced into the diffusion chamber 242b of the shower head 240b via the pipe 300a is discharged from the gas discharge holes 244b toward the wafer W mounted on the susceptor 222. In addition, the precursor gas introduced into the diffusion chamber 242c of the shower head 240b via the pipe 300b is discharged from the gas discharge holes 244c toward the wafer W mounted on the susceptor 222. Then, the precursor gas discharged from the gas discharge holes 244b and the precursor gas discharged from the gas discharge holes 244c are mixed inside the film formation chamber 200.

According to the vaporizer of an embodiment of the present disclosure, it is possible to stably prevent a nozzle from clogging.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A vaporizer comprising:
a gas-liquid mixer configured to mix a solution containing a precursor and a carrier gas;
a nozzle configured to inject the solution containing the precursor mixed by the gas-liquid mixer;
a vaporization chamber in which the solution containing the precursor injected by the nozzle is vaporized;
a first temperature adjustment mechanism configured to adjust a temperature of the vaporization chamber;
a second temperature adjustment mechanism configured to adjust a temperature of the gas-liquid mixer;
a third temperature adjustment mechanism configured to adjust a temperature of the nozzle; and
a control device configured to control the first temperature adjustment mechanism to adjust the temperature of the vaporization chamber to a first temperature higher than a vaporization temperature of the precursor, to control the second temperature adjustment mechanism to adjust the temperature of the gas-liquid mixer to a second temperature than the first temperature, and to control the third temperature adjustment mechanism to adjust the temperature of the nozzle to a third temperature which falls within a temperature range between the first temperature and the second temperature and is lower than a vaporization temperature of a solvent of the solution.

2. The vaporizer of claim 1, wherein the third temperature corresponds to an intermediate value between the first temperature and the second temperature and is lower than the vaporization temperature of the solvent of the solution.

3. The vaporizer of claim 1, wherein the first temperature is higher than the vaporization temperature of the precursor and is lower than a temperature at which the precursor is thermally decomposed.

4. The vaporizer of claim 1, wherein the second temperature adjustment mechanism is further configured to adjust a temperature of a carrier gas supply pipe for supplying the carrier gas into the gas-liquid mixer, and
wherein the control device is further configured to control the second temperature adjustment mechanism to adjust the temperature of the gas-liquid mixer and the temperature of the carrier gas supply pipe to the second temperature.

5. The vaporizer of claim 1, wherein the precursor is Li(TMHD), and
wherein, assuming that an internal pressure of the vaporization chamber is Ph [kPa], the temperature of the gas-liquid mixer is Tm [degrees C.], and the vaporization temperature of the solvent of the solution is Tsov [degrees C.],
Ph<29 (1)
Tsov>{11.94In(Ph)+157.38+Tm}/2 (2)
the solvent of the solution is selected so that the above equations (1) and (2) are satisfied.

6. The vaporizer of claim 1, wherein the precursor is Li(TMHD) and Co(TMHD)₃, and
wherein, assuming that an internal pressure of the vaporization chamber is Ph [kPa], the temperature of the gas-liquid mixer is Tm [degrees C.], and the vaporization temperature of the solvent of the solution is Tsov [degrees C.],
Ph<29 (3)
Tsov>{11.94In(Ph)+157.38+Tm}/2 (4)
the solvent of the solution is selected so that the above equations (3) and (4) are satisfied.

7. The vaporizer of claim 1, wherein the precursor is Co(TMHD)₃, and wherein, assuming that an internal pressure of the vaporization chamber is Ph [kPa], the temperature of the gas-liquid mixer is Tm [degrees C.], and the vaporization temperature of the solvent of the solution is Tsov [degrees C.],
Ph<1.01 (5)
Tsov>{17.744In(Ph)+45.483+Tm}/2. (6)
the solvent of the solution is selected so that the above equations (5) and (6) are satisfied.

8. A film forming apparatus comprising:
a vaporizer configured to generate a precursor gas by vaporizing a solution containing a precursor; and
a film formation chamber in which a film forming process is performed using the precursor gas generated by the vaporizer,
wherein the vaporizer includes:
a gas-liquid mixer configured to mix the solution containing the precursor and a carrier gas;
a nozzle configured to inject the solution containing the precursor mixed by the gas-liquid mixer;
a vaporization chamber in which the solution containing the precursor injected by the nozzle is vaporized;
a first temperature adjustment mechanism configured to adjust a temperature of the vaporization chamber;
a second temperature adjustment mechanism configured to adjust a temperature of the gas-liquid mixer;
a third temperature adjustment mechanism configured to adjust a temperature of the nozzle; and
a control device configured to control the first temperature adjustment mechanism to adjust the temperature of the vaporization chamber to a first temperature higher than a vaporization temperature of the precursor, to control the second temperature adjustment mechanism to adjust the temperature of the gas-liquid mixer to a second temperature lower than the first temperature, and to control the third temperature adjustment mechanism to adjust the temperature of the nozzle to a third temperature which falls within a temperature range between the first temperature and the second temperature and is lower than a vaporization temperature of a solvent of the solution.

9. A temperature control method performed by a vaporizer including:
a gas-liquid mixer configured to mix a solution containing a precursor and a carrier gas;
a nozzle configured to inject the solution containing the precursor mixed by the gas-liquid mixer;
a vaporization chamber in which the solution containing the precursor injected by the nozzle is vaporized;
a first temperature adjustment mechanism configured to adjust a temperature of the vaporization chamber;
a second temperature adjustment mechanism configured to adjust a temperature of the gas-liquid mixer; and
a third temperature adjustment mechanism configured to adjust a temperature of the nozzle,
the method comprising:
adjusting, by the first temperature adjustment mechanism, the temperature of the vaporization chamber to a first temperature higher than a vaporization temperature of the precursor;
adjusting, by the second temperature adjustment mechanism, the temperature of the gas-liquid mixer to a second temperature lower than the first temperature; and
adjusting, by the third temperature adjustment mechanism, the temperature of the nozzle to a third temperature which falls within a temperature range between the first temperature and the second temperature and is lower than a vaporization temperature of a solvent of the solution.
